(19) United States
(12) Patent Application Publication
(10) Pub. No.: US 2014/0069482 A1
(43) Pub. Date: Mar. 13, 2014

(54) Solar Roofing Tiles and Manufacturing Method Thereof

(71) Applicants: XIAOPENG HONG, Fuyang (CN); SHENGYAO HOU, Fuyang (CN); QINGFENG HE, Fuyang (CN); LINGJUAN WANG, Fuyang (CN)

(72) Inventors: XIAOPENG HONG, Fuyang (CN); SHENGYAO HOU, Fuyang (CN); QINGFENG HE, Fuyang (CN); LINGJUAN WANG, Fuyang (CN)

(73) Assignee: Zhejiang Heda Solar Technology Co. Ltd., Fuyang (CN)

(21) Appl. No.: 13/904,330

(22) Filed: May 29, 2013

(30) Foreign Application Priority Data
Sep. 12, 2012 (CN) 201210327876.8

(51) Int. Cl. H01L 31/048

(52) U.S. Cl. CPC H01L 31/0483
USPC 136/246; 156/242

(57) ABSTRACT

The present invention relates a solar roofing tile and manufacturing method thereof. A solar roofing tile comprises a substrate and a solar cell mounted on the substrate. The upper surface of substrate is provided with a zebra vein. The manufacturing method is to make substrate first and then coat dark glaze material to the surface of substrate to form dark vein. The part of substrate without coating glaze material forms a white vein. The dark vein and the white vein constitute zebra veins. Finally bond solar module to the substrate. The object of the present invention is to provide a solar roofing tile to promote air circulation on substrate surface and its manufacturing method to solve the problem of poor heat dissipation, poor efficiency in hot days and hence poor thermal insulation in existing photovoltaic tile.

### CROSS REFERENCE TO RELATED PATENT APPLICATION

The present application claims the priority of Chinese patent application No. 201210327876.8 filed on Sep. 7, 2012, which application is incorporated herein by reference.

### FIELD OF THE INVENTION

The present invention relates to solar roofing tiles and manufacturing method thereof, belonging to the field of photovoltaic cells.

### DESCRIPTION OF THE PRIOR ART

With the increasing progress of economic development and all-sided construction of well-being society, the building industry has got rapid development. The energy consumption in building industry is steadily increased, in which the most energy consumption is the air conditioning system for heating and refrigeration, making up 60%-70% of general energy consumption in building industry.

As a regenerated green energy, solar energy has received broad attention both at home and abroad in recent years. By making solar modules on roof tiles, solar roofing tiles can not only realize energy saving, but also transfer solar lighting resource to the electricity needed in life and save the installation space of solar modules without occupying precious land. For example, Chinese Patent 2010206909617 (Date of Authorized Announcement: 2011-11-9) entitled “Flat photovoltaic tiles” has disclosed a photovoltaic tile that comprises a substrate of photovoltaic tile and solar module mounted on the substrate.

The existing solar roofing tiles have the following shortcomings: only considering the utilization of solar energy but failing to effectively dissipate the heat of solar energy absorbed by the parts of the substrate that are not covered by solar modules, resulting in poor heat dissipation, low efficiency and poor thermal insulation and hence the small difference between inside temperature and outside temperature; Poor reliability of connection between the substrate and solar modules; Low rate of qualified products.

### SUMMARY OF THE INVENTION

The first object of the present invention is to provide a solar roofing tile to promote air circulation on substrate surface and its manufacturing method to solve the problem of poor heat dissipation, poor efficiency in hot days and hence poor thermal insulation in existing photovoltaic tile.

The second object of the present invention is to improve the fastness of connection between a solar module and a substrate and its manufacturing method to solve the problem of poor connection between a solar module and a substrate in existing photovoltaic tile.

The third object of the present invention is to provide a photovoltaic tile manufacturing method that can promote the rate of qualified products and production efficiency to solve the problem of poor production efficiency and poor rate of qualified products in existing photovoltaic tile production.

The above-mentioned technical problems are to be solved by the following technical scheme: a solar roofing tile comprises a substrate and a solar module mounted on the substrate. The upper surface of said substrate is provided with a zebra vein. Exposed in sunshine, the white veins in the zebra veins reflect most sunshine but adsorb less heat, featuring a low surface temperature; while the dark veins in the zebra veins adsorb more heat, featuring a high surface temperature. Hence, the air temperature over white veins is lower than that over dark veins. The air over the two veins forms a pressure difference to promote air circulation and cause a circulating wind on the surface of the photovoltaic tiles, so that the wind effects heat dissipation on the photovoltaic tiles. Heat is dissipated to the air and the substrate temperature rises slowly and less, so that the thermal insulation of the photovoltaic tile is improved. The zebra veins can take stripe, annular or spot form. However the experiment has shown that stripe veins effect the best heat dissipation but spot veins effect the worst heat dissipation.

Preferably, the substrate is rectangle and the zebra veins are stripe. The said zebra veins extend from one side of substrate to the other side, constituting a straight line from the starting end to the terminal end of the zebra veins that is parallel to the side of substrate. When the photovoltaic tiles of the present invention are installed on the roof, the dark stripes of neighboring photovoltaic tiles are butt jointed while the white stripes of neighboring photovoltaic tiles are also butt jointed, so as to forming oversized color block of zebra veins to improve the air circulation on photovoltaic tile surface. Only one specification of photovoltaic tile required to form oversized color block of zebra veins can greatly improve the convenience in photovoltaic tile manufacturing and roofing installation.

Preferably, the zebra veins are stripe and are easily made.

Preferably, the solar modules are situated at the dark veins in the zebra veins, Thus speeding up the evaporation of the water on the surface of solar modules after a storm comes a calm, reducing said rain water's blocking of light ray that illuminates the solar modules, and improving the utilization ratio of sunlight.

Preferably, light-reflect troughs are provided on the surface of substrate. The transverse section of the trough is arc. The troughs are situated at the white vein in the zebra veins while the light band formed by the light-reflect trough is situated over the dark vein in the zebra veins. When sunlight illuminates the parabolic troughs, the light-reflect trough forms a light band that is situated over dark vein, so as to raise the temperature over the dark vein and further promote air circulation over the surface of photovoltaic tile to enhance heat dissipation.

Preferably, the substrate comprises a substrate main body, an arc upper cover side at the side of substrate main body, a lower cover side at the other side of substrate main body. The upper cover side, substrate main body and lower cover side constitute a groove structure. The light-reflect trough are provided at both sides of the upper cover side. When the photovoltaic tiles are installed on the roof, in the neighboring two photovoltaic tiles, the upper cover side of one photovoltaic tile locks the lower cover side of the other photovoltaic tile, thus realizing the waterproof connection of photovoltaic tiles. Such a structure features a good coherence.

Preferably, the solar module is situated at the substrate with the upper surface of solar module being level with or slightly higher than the upper surface of substrate. No water can be retained on the surface of solar modules, thus reducing said water's blocking of light ray that illuminates the solar modules and improving the utilization ratio of sunlight; Water cannot easily penetrate the solar module. The solar module and the substrate as well as the solar module itself can hardly be separated. Therefore, the photovoltaic tile of the present invention features a good safety and a long service life.

Preferably, the substrate is provided with a through hole penetrating the upper and lower surfaces of the substrate. The through hole is a platform hole with a large opening at upper end and a small opening at lower end. The solar module is mounted on the platform of through hole and bonded with an adhesive layer. The adhesive layer includes a butyl hot melt adhesive layer and a silica gel layer. The butyl hot melt adhesive layer covers and is bonded with the side and top of the solar module while silica gel layer covers and is bonded with the wall and step of the through hole as well as the bottom of solar module. The butyl hot melt adhesive layer and the silica gel layer are bonded together. Both layers take annular forms. Both silica gel and butyl hot melt adhesive are used to bond the solar module to the substrate according to their structure and position in the technical scheme, Fully utilizing the bonding power, aging resistance and stabilization of silica gel and the leakproofhess of butyl hot melt adhesive, guaranteeing good waterproofness and reliable connection of photovoltaic tile and more convenient installation. The adhesive layer covering the face of solar module can preferably prevent water from seeping in the solar module.

A method of manufacturing solar roofing tile is characterized by:

Step 1: manufacturing the substrate

Step 1 includes:

Step 101: mix the raw material for manufacturing the substrate until smooth with a mixer. Raw material is existing material and appears white after solidification when no color agent or pigment is added.

Step 102: weigh well mixed raw material according to the weight of substrate;

Step 103: input the well weighed raw material in the mould to manufacture the substrate;

Step 104: heat the mould to manufacture the substrate to 280-320° C. and retain the temperature for 5-7 minutes so as to allow the raw material to be solidified to substrate in the mould;

Step 105: cool the mould to <150° C.;

Step 106: take the substrate out of the mould and cool it in room temperature;

Step 107: coat black or other dark glaze material on the upper surface of the substrate main body to make dark vein. The part of substrate without coating glaze material forms a white vain. The white vein and the above-mentioned dark vein constitute zebra veins; to promote light-reflecting effect of the white vein, it is advisable to coat white glaze material that features good light reflection. To promote light-reflecting effect of the white vein, it is advisable to coat white glaze material that features good light reflection.

Step 2: mount solar module on the substrate;

Step 2 includes:

Step 201: apply a layer of silica gel on the step face of through hole in the substrate;

Step 202: apply a layer of butyl hot melt adhesive on the side and face of solar module;

Step 203: mount the solar module coated with butyl hot melt adhesive on the step of through hole in the substrate coated with silica gel. Press the solar module until the silica gel on the step seeps upwards and downwards along the wall of through hole; the butyl hot melt adhesive, after being solidified, forms a butyl hot melt adhesive layer. The silica gel, after being solidified, forms a silica gel layer. The butyl hot melt adhesive layer and the silica gel layer are bonded together.

Preferably, the weight of raw material at Step 203 should exceed that of substrate; At Step 202, the butyl hot melt adhesive on the side and face of solar module is simultaneously coated using a L-type nozzle; At Step 203, not until the butyl hot melt adhesive is in semi-solidified state and at a temperature of 75-90° C., mount the solar module in the through hole of the substrate. Heavier weight of raw material than that of substrate can prevent the deficiency of substrate manufactured and improve the rate of qualified products. Preferably, the heavier weight is 5 g, thus fully utilizing the material and improving the rate of qualified products. Coating adhesives both at the side and face can improve production efficiency, cohesion result, planeness of pressed adhesives and the facility in the mounting of the substrate. When butyl hot melt adhesive is in semi-solidified state at the temperature of 75-90° C., it is the best time to mount the solar module to the substrate, reducing the mutual influence between silica gel and butyl hot melt adhesive and obtaining a better connection.

Preferably, in step 105 and 103, reducing temperature is conducted by the means of air cooling.

The present invention has the following advantages:

1. The zebra veins of the substrate enable the air on the surface of photovoltaic tile to circulate, thus reducing the temperature of the surface of photovoltaic tile as well as that of inside house;

2. Using solar module to transfer solar energy to electric energy can effectively reduce building energy consumption;

3. Using low-temperature moulding process to produce the substrate can reduce energy consumption in producing the substrate, and meanwhile guarantee the substrate to be non-shrinkable and non-deformable;

4. Using silica gel and butyl hot melt adhesive at the same time and the control of adhesives temperature can effectively guarantee the sealing property for the products;

5. Coating the adhesives at the same time using L-type nozzle can obtain high encapsulation efficiency and accuracy and reduce the application amount of adhesives;

6. Reducing temperature by the means of air cooling enables the adhesives to rapidly solidified and allows synchronous encapsulation, packaging and warehousing.

7. Reducing temperature by the means of air cooling can improve the efficiency of photovoltaic tiles in hot days.

### BRIEF DESCRIPTION OF THE DRAWINGS

FIG. 1 is a sectional view of solar roofing tile in example 1 of the present invention.

FIG. 2 is a top view of solar roofing tile in example 1 of the present invention.

FIG. 3 is a top view of solar roofing tile which substrate is not coated with deep color stripe in example 1 of the present invention.

FIG. 4 is a top view of solar roofing tile which substrate is coated with deep color stripe in example 1 of the present invention.

FIG. 5 is a top view of solar roofing tile which substrate is coated with silica gel (black stripe not shown in the figure) in example 1 of the present invention.

FIG. 6 is a sectional view along A-A line of FIG. 5.

FIG. 7 is a top view of solar roofing tile which solar modules are coated with butyl hot melt adhesive in example 1 of the present invention.

FIG. 8 is a sectional view along B-B line of FIG. 7.

FIG. 9 is a 3-dimensional view of the nozzle used in manufacturing the solar roofing tiles of the present invention.

FIG. 10 is a sectional view of solar roofing tile in example 2 of the present invention.

FIG. 11 is a sectional view of two solar roofing tiles connected together in example 2 of the present invention.

In the figures: substrate 1, substrate main body 11, upper cover side 12, lower cover side 13, through hole 14, parabolic trough 15, solar module 2, adhesive layer 3, butyl hot melt adhesive layer 31, silica gel layer 32, silica gel 4, butyl hot melt adhesive 5, nozzle 6, spout 61, light ray 7, light band 8, width of the face part of solar module covered by butyl hot melt adhesive L.

### DETAILED DESCRIPTION OF THE PREFERRED EMBODIMENTS

Reference will now be made in greater detail to exemplary embodiments of the present invention with reference to the accompanying drawings.

Example 1: as shown in FIG. 1, a solar roof file, comprising a substrate 1, a solar module 2 and adhesive layer 3.

The substrate 1 includes a substrate main body 11, an upper cover side 12 on the left side of the substrate main body 11, and a lower cover side 13 on the right side of the substrate main body 11. The upper cover side 12 takes an arch shape. The upper cover side 12, substrate main body 11 and lower cover side 13 constitute a groove structure.

The substrate main body 11 is provided with a through hole 14 penetrating the upper and lower surfaces of the substrate. The through hole 14 is a step hole with a large opening at upper end and a small opening at lower end. The solar module 2 is placed on the step of through hole 14 and bonded to the substrate 1 with the adhesive layer 3.

The adhesive layer 3 comprises a butyl hot melt adhesive layer 31 and a silica gel layer 32. Both butyl hot melt adhesive layer 31 and the silica gel layer 32 take a circular shape. The butyl hot melt adhesive layer 31 covers and is bonded on the side and top of the solar module 2. The silica gel layer 32 covers and is bonded on the wall and step of the through hole 14 as well as the bottom of solar module 2. The butyl hot melt adhesive layer 31 and the silica gel layer 32 are bonded together. The upper surface of solar module 2 is higher than that of substrate main body 11.

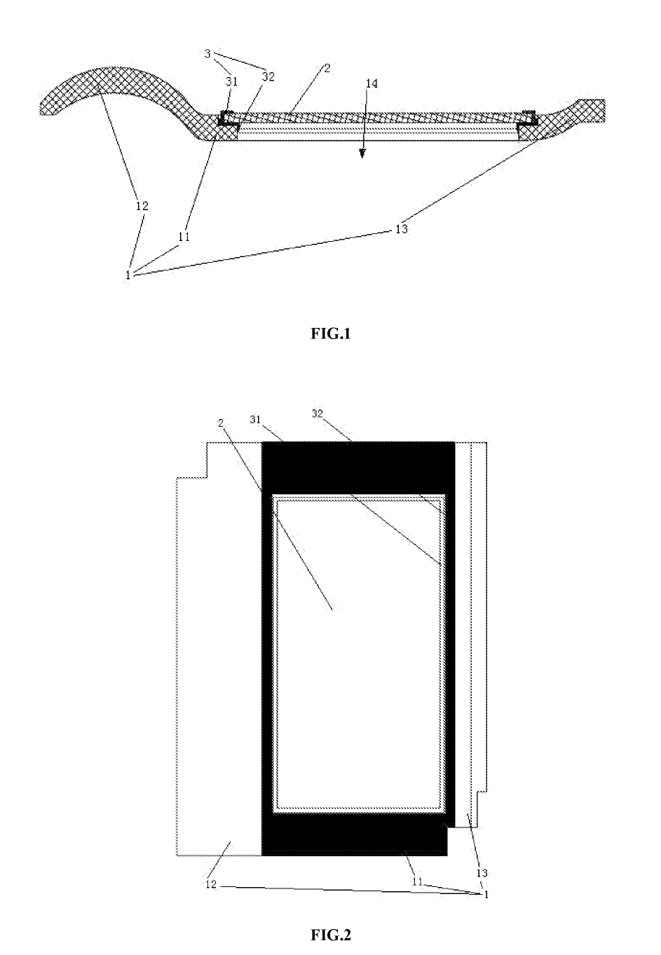

As shown in FIG. 2, the substrate 1 take a rectangle shape. Both upper surfaces of upper cover side 12 and lower cover side 13 are white and the white color constitutes a white vertical stripe from the front side to the rear side of the substrate 1. The upper surface of substrate main body 11 is black and the black color constitutes a black vertical stripe from the front side to the rear side of the substrate 1. The vertical white stripe and vertical black stripe jointly form a vertical zebra stripe on the surface of the substrate 1. The straight line defined by the front and rear of black stripe is parallel to the left and right sides of the substrate 1.

The solar roofing tiles are manufactured as the following procedure:

Step 1: manufacturing the substrate

Step 1 includes:

Step 101: mix the raw material for manufacturing the substrate until smooth with a mixer.

The raw material to feed in the mixer every time is no more than 200 KG and mixing time is about 30 minutes. No water or other impurity shall be allowed to enter the mixer during mixing.

Step 102: weigh well mixed raw material according to the weight of substrate. The weight of raw material should be 5 g more than the weight of roofing tile.

Step 103: input the well weighed raw material in the mould to manufacture the substrate;

Step 104: heat the mould to manufacture the substrate to 280° C. and retain the temperature for 5 minutes so as to allow the raw material to be solidified to substrate in the mould;

Step 105: cool the mould to <150° C. with an air cooling device;

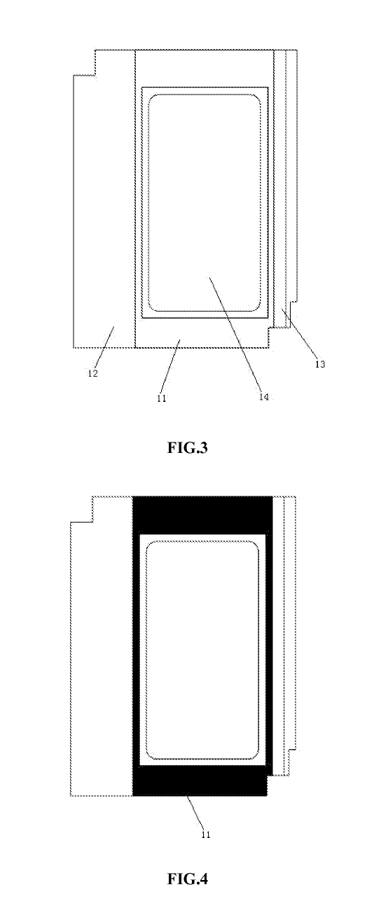

Step 106: take the substrate out of the mould and cool it in room temperature. The structure of substrate taken out of the mould is as shown in FIG. 3.

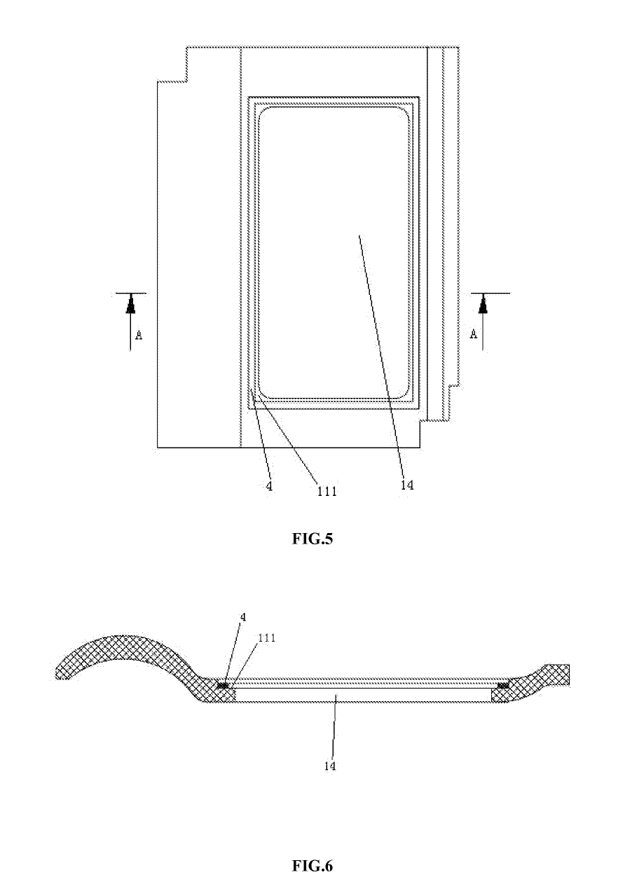

Step 107: as shown in FIG. 4, coat black or other dark glaze material on the upper surface of the substrate main body 11 to make dark vertical stripe. The part of substrate 1 without coating glaze material is white, appearing a vertical white stripe. The vertical white stripe and the above-mentioned vertical dark stripe constitute vertical zebra veins;

Step 2: mount solar module on the substrate;

Step 2 includes:

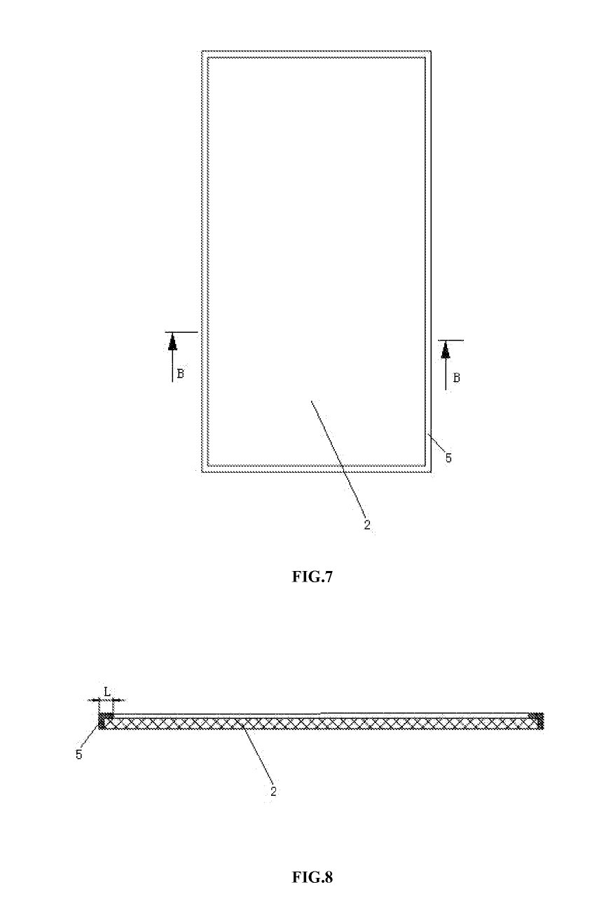

Step 201: as shown in FIG. 5, fix the substrate 1 on a worktable and apply a layer of silica gel 4 on the step face 111 of through hole in the substrate 1; the silica gel 4 spread circumferentially throughout the step face 111 of through hole, forming a ring shape. As shown in FIG. 6, the thickness of silica gel applied is half the distance from the step face 111 of through hole to the upper surface of the substrate main body 11. The width of silica gel applied is less than that of step face 111 of through hole.

Step 202: as shown in FIG. 7, apply a layer of butyl hot melt adhesive 5 on the circumferentia of solar module 2; as shown in FIG. 8, cover the side and face of solar module 2 with the butyl hot melt adhesive 5. The butyl hot melt adhesive 5 is 2 mm thick and the width L of the face part of solar module covered by butyl hot melt adhesive is 6 mm. The transverse section of butyl hot melt adhesive 5 is “7” shape. The butyl hot melt adhesive 5 on the side and face of solar module 2 is coated at the same time by the nozzle shown in FIG. 9. The nozzle 6 is provided with a “7”-shaped spout 61. The coating speed is 0.1 m/s and the adhesive discharging temperature is controlled at 120-130° C.

Step 203: as shown in FIG. 1, when the butyl hot melt adhesive is in semi-solidified state and at a temperature of 75-90° C., mount the solar module 2 coated with the butyl hot melt adhesive on the step of through hole 14 in the substrate coated with silica gel. Press the solar module 2 until the silica gel on the step seeps upwards and downwards along the wall of through hole. The butyl hot melt adhesive, after being solidified, forms a butyl hot melt adhesive layer 31. The silica gel, after being solidified, forms a silica gel layer 32. The butyl hot melt adhesive layer 31 and the silica gel layer 32 are bonded together.

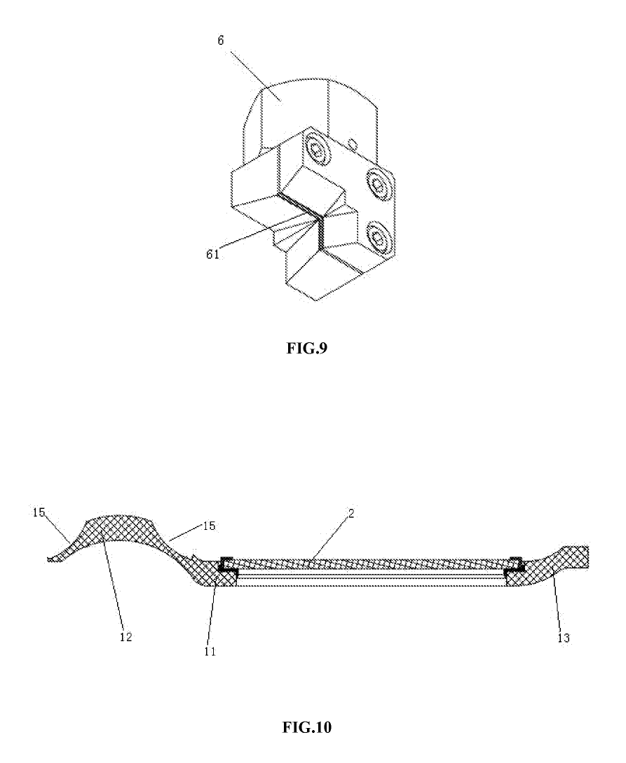

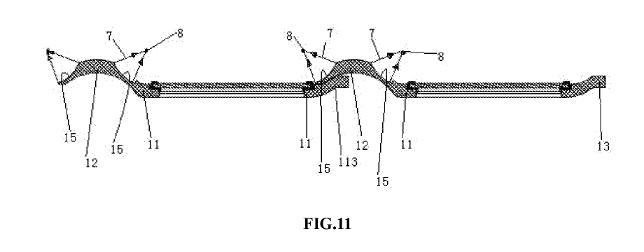

Example 2: as shown in FIG. 10, the difference from example 1 lies in those parabolic troughs 15 are provided at both left and right sides of upper cover side 12. The transverse section of parabolic trough 15 is an arc. The upper surface of solar module 2 is level with that of the substrate main body 11.

At step 107, coat white sub-shine glaze material on the upper surfaces of both upper cover side 12 and lower cover side 13 to constitute vertical white stripe. The purpose of coating white sub-shine glaze material is to promote the effect of white stripe to reflect the light.

At step 104, heat the mould to manufacture the substrate to 320° C. and retain the temperature for 7 minutes.

As shown in FIG. 11, during operation, the parabolic troughs 15 reflect the light ray 7 to form a light band 8 over the substrate main body 11.

In the above-mentioned examples, the zebra vein on the surface of substrate is stripe. Apparently, the veins can take wave, annular or spot form.

What is claimed is:

1. A solar roofing tile, comprising a substrate and a solar module mounted on the substrate, wherein the upper surface of said substrate is provided with a zebra vein.

2. The solar roofing tile as claimed in claim 1, wherein the substrate is rectangle and the zebra veins are stripe; the said zebra veins extend from one side of substrate to the other side, constituting a straight line from the starting end to the terminal end of the zebra veins that is parallel to the side of substrate.

3. The solar roofing tile as claimed in claim 2, wherein the said zebra veins are stripe.

4. The solar roofing tile as claimed in claim 1, or 3, wherein the said solar module are situated at the dark veins in the zebra veins.

5. The solar roofing tile as claimed in claim 1 or, wherein light-focus troughs are provided on the surface of substrate; the transverse section of the trough is arc; the troughs are situated at the white vein in between the zebra veins while the light band formed by the light-focus troughs is situated over the dark vein in the zebra veins.

6. The solar roofing tile as claimed in claim 5, wherein the said substrate comprises a substrate main body, an arc upper cover side at the side of substrate main body, a lower cover side at the other side of substrate main body. The upper cover side, substrate main body and lower cover side constitute a groove structure. The light-focus troughs are provided at both sides of the upper cover side.

7. The solar roofing tile as claimed in claim 6, wherein the said solar cell is situated at the substrate with the upper surface of solar cell being level with or slightly higher than the upper surface of substrate.

8. The solar roofing tile as claimed in claim 1, wherein the said substrate is provided with a through hole penetrating the upper and lower surfaces of the substrate; the said through hole is a step hole with a large opening at upper end and a small opening at lower end; the said solar module is mounted on the step of through hole and bonded with an adhesive layer; the said adhesive layer includes a butyl hot melt adhesive layer and a silica gel layer; the said butyl hot melt adhesive layer covers and is bonded with the side and top of the solar module while the said silica gel layer covers and is bonded with the wall and step of the through hole as well as the bottom of solar module; the said butyl hot melt adhesive layer and the said silica gel layer are bonded together; both layers take annular forms.

9. A method of manufacturing solar roofing tile as claimed in claim 1, wherein:
Step 1: manufacturing the substrate
Step 1 includes the following steps:
Step 101: mix the raw material for manufacturing the substrate until smooth with a mixer;
Step 102: weigh well mixed raw material according to the weight of substrate;
Step 103: input the well weighed raw material in the mould to manufacture the substrate;
Step 104: heat the mould to manufacture the substrate to 280-320° C. and retain the temperature for 5-7 minutes so as to allow the raw material to be solidified to substrate in the mould;
Step 105: cool the mould to <150° C.;
Step 106: take the substrate out of the mould and cool it in room temperature;
Step 107: coat black or other dark glaze material on the upper surface of the substrate main body to make dark vein. The part of substrate without coating glaze material forms a white vain. The white vein and the above-mentioned dark vein constitute zebra veins;
Step 2: mount solar cell on the substrate;
Step 2 includes the following steps:
Step 201: apply a layer of silica gel on the step face of through hole in the substrate;
Step 202: apply a layer of butyl hot melt adhesive on the side and face of solar cell;
Step 203: mount the solar cell coated with butyl hot melt adhesive on the step of through hole in the substrate coated with silica gel. Press the solar cell until the silica gel on the step seeps upwards and downwards along the wall of through hole; the butyl hot melt adhesive, after being solidified, forms a butyl hot melt adhesive layer. The silica gel, after being solidified, forms a silica gel layer. The butyl hot melt adhesive layer and the silica gel layer are bonded together.

10. The method of manufacturing solar roofing tile as claimed in claim 9, wherein the weight of raw material at Step 102 should exceed that of substrate; At Step 202, the butyl hot melt adhesive on the side and face of solar cell is simultaneously coated using a L-type nozzle; At Step 203, not until the butyl hot melt adhesive is in semi-solidified state and at a temperature 75-90° C., mount the solar cell in the through hole of the substrate.

11. The solar roofing tile as claimed in claim 2, wherein the said solar module are situated at the dark veins in the zebra veins.

12. The solar roofing tile as claimed in claim 3, wherein the said solar module are situated at the dark veins in the zebra veins.

13. The solar roofing tile as claimed in claim 2, wherein light-focus troughs are provided on the surface of substrate; the transverse section of the trough is arc; the troughs are situated at the white vein in between the zebra veins while the light band formed by the light-focus troughs is situated over the dark vein in the zebra veins.

14. The solar roofing tile as claimed in claim 3, wherein light-focus troughs are provided on the surface of substrate; the transverse section of the trough is arc; the troughs are situated at the white vein in between the zebra veins while the light band formed by the light-focus troughs is situated over the dark vein in the zebra veins.

15. The solar roofing tile as claimed in claim 2, wherein the said substrate is provided with a through hole penetrating the upper and lower surfaces of the substrate; the said through hole is a step hole with a large opening at upper end and a small opening at lower end; the said solar module is mounted on the step of through hole and bonded with an adhesive layer; the said adhesive layer includes a butyl hot melt adhesive layer and a silica gel layer; the said butyl hot melt adhesive layer covers and is bonded with the side and top of the solar module while the said silica gel layer covers and is bonded with the wall and step of the through hole as well as the bottom of solar module; the said butyl hot melt adhesive layer and the said silica gel layer are bonded together; both layers take annular forms.

16. The solar roofing tile as claimed in claim 3, wherein the said substrate is provided with a through hole penetrating the upper and lower surfaces of the substrate; the said through hole is a step hole with a large opening at upper end and a small opening at lower end; the said solar module is mounted on the step of through hole and bonded with an adhesive layer; the said adhesive layer includes a butyl hot melt adhesive layer and a silica gel layer; the said butyl hot melt adhesive layer covers and is bonded with the side and top of the solar module while the said silica gel layer covers and is bonded with the wall and step of the through hole as well as the bottom of solar module; the said butyl hot melt adhesive layer and the said silica gel layer are bonded together; both layers take annular forms.
